(19) United States
(12) Patent Application Publication
(10) Pub. No.: US 2021/0045227 A1
(43) Pub. Date: Feb. 11, 2021

(54) Component Carrier, Method of Manufacturing the Same and Method of Shielding a Structural Feature in a Component Carrier

(71) Applicant: AT&S Austria Technologie & Systemtechnik Aktiengesellschaft, Leoben (AT)

(72) Inventor: Günther Mayr, Milpitas, CA (US)

(21) Appl. No.: 16/535,419

(22) Filed: Aug. 8, 2019

(51) Int. Cl. H05K 1/02; H05K 3/06

(52) U.S. Cl. CPC H05K 1/024; H05K 3/06

(57) ABSTRACT

A component carrier, a method of manufacturing the same and a method of shielding a structural feature in a component carrier are disclosed. The component carrier includes a laminated stack with a plurality of electrically conductive layer structures and a plurality of electrically insulating layer structures; an electrically insulating cap structure selectively covering a structural feature at an exterior surface of the laminated stack; and a shielding structure on the cap structure for shielding the structural feature.

### TECHNICAL FIELD

The invention relates to a component carrier, to a method of manufacturing the same, and to a method of shielding a structural feature in a component carrier.

### TECHNOLOGICAL BACKGROUND

A conventional component carrier comprises a laminated stack having a plurality of electrically conductive layer structures and a plurality of electrically insulating layer structures. Conductive traces are arranged on the stack. Especially in RF modules and other high frequency product applications such as 5G applications as well as in Solid State Drives (SSD), where for example critical signals are routed via the traces on the outermost layer over a bend region, the signal integrity is an issue. Usually, shields made of prefabricated metal sheets are surface-mounted by a mounting or assembling machine in a separate manufacturing step to cover and shield the traces. However, such shields can be mounted only to specific areas of the component carrier. Furthermore, the size of the component carrier is increased by such shields.

### SUMMARY

There is a need to provide a component carrier having improved signal integrity and a smaller size, to provide a simplified method of manufacturing the component carrier, and to provide a method of shielding a structural feature in a component carrier. This need is achieved by the subject matters of the independent claims.

According to an exemplary embodiment of the invention, there is provided a component carrier, the component carrier comprises a laminated stack having a plurality of electrically conductive layer structures and a plurality of electrically insulating layer structures; an electrically insulating cap structure selectively covering a structural feature at an exterior surface of the laminated stack; and a shielding structure on the cap structure for shielding the structural feature.

According to another exemplary embodiment of the invention, there is provided a method of manufacturing a component carrier, the method comprises providing a laminated stack having a plurality of electrically conductive layer structures and a plurality of electrically insulating layer structures; forming an electrically insulating cap structure selectively covering a structural feature at an exterior surface of the laminated stack; and forming a shielding structure on the cap structure for shielding the structural feature.

According to the present invention, a separate step of assembling or mounting a shielding or shield, which is conventionally made of a metal sheet, can be omitted so that the manufacturing method is simplified and costs are reduced. The shielding structure or shield according to the present invention can be arranged at any location of the component carrier and not only at specific areas of a conventional component carrier. Furthermore, the component carrier can be provided in any size and in a compact size, in particular if the shielding structure or shield is manufactured by plating, sputtering and/or three-dimensional printing. Any sputterable material can be used for the shielding structure.

According to another exemplary embodiment of the invention, there is provided a method of shielding a structural feature in a component carrier, wherein the method comprises a step of using a component carrier, wherein the component carrier comprises a laminated stack having a plurality of electrically conductive layer structures and a plurality of electrically insulating layer structures; an electrically insulating cap structure selectively covering the structural feature at an exterior surface of the laminated stack; and a shielding structure on the cap structure for shielding the structural feature.

In all embodiments, even critical signals, which are routed on inner or outer layers, can be shielded at the top and/or bottom sides of the structural feature. The shielding structure can be configured to protect a signal integrity of any signal being transported within the structural feature, which particularly includes electric and optical signals. For example, the component carrier according to the present invention can shield traces between antenna arrays from external sources and can ensure increased performance due to reduced impact of noise or disturbances, in particular for 5G or other RF applications with antenna arrays on an external layer. The shielding structure can furthermore have benefits for a mechanical protection of the structural feature.

### OVERVIEW OF EMBODIMENTS

In the following, further exemplary embodiments of the present invention will be explained.

In an embodiment, the electrically insulating cap structure is a solder resist so that the shielding structure is arranged on the solder resist.

In an embodiment, the structural feature, the cap structure and the shielding structure are formed on both opposing main surfaces of the laminated stack so that the structural feature can be shielded at the top and bottom sides.

In an embodiment, in a cross-sectional view, the cap structure is substantially U-shaped. In an embodiment, in a cross-sectional view, the shielding structure is substantially U-shaped. As a result, the structural feature can be shielded even at the lateral sides.

In an embodiment, the structural feature is at least one of an electrically conductive trace, an electrically conductive pad of the electrically conductive layer structures, an optical wave guide such as a glass fiber structure, and a connection structure connected to an antenna structure. In an embodiment, the structural feature is a component, in particular a passive or an active component such as a semiconductor. The shielding structure can be adapted to any shape of the structural feature.

In an embodiment, the shielding structure shields at least against one of electromagnetic radiation, in particular high-frequency radiation, heat radiation, infrared radiation, light, and humidity; and/or the shielding structure is configured to protect a signal integrity of a signal being transported within the structural feature.

In an embodiment, on top of the shielding structure, at least one of a surface finish and a further solder resist is formed.

In an embodiment, the component carrier comprises at least one of the following features: the component carrier comprises at least one component being surface mounted on and/or embedded in the component carrier, wherein the at least one component is in particular selected from a group consisting of an electronic component, an electrically non-conductive and/or electrically conductive inlay, a heat transfer unit, a light guiding element, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier, and a logic chip; wherein at least one of the electrically conductive layer structures of the component carrier comprises at least one of the group consisting of copper, aluminum, nickel, silver, gold, palladium, and tungsten, any of the mentioned materials being optionally coated with supra-conductive material such as graphene; wherein the shielding structure comprises at least one of the group consisting of copper, aluminum, nickel, silver, gold, palladium, and tungsten, any of the mentioned materials being optionally coated with supra-conductive material such as graphene; wherein the electrically insulating layer structure comprises at least one of the group consisting of resin, in particular reinforced or non-reinforced resin, for instance epoxy resin or bismaleimide-triazine resin, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide; wherein the electrically insulating cap structure comprises at least one of the group consisting of resin, in particular reinforced or non-reinforced resin, for instance epoxy resin or bismaleimide-triazine resin, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide, a resin, and a mold compound, wherein the component carrier is shaped as a plate; wherein the component carrier is configured as one of the group consisting of a printed circuit board, a substrate, and an interposer; wherein the component carrier is configured as a laminate-type component carrier.

In an embodiment of the method of manufacturing, the electrically insulating cap structure is a solder resist.

In an embodiment of the method of manufacturing, the structural feature, the cap structure and the shielding structure are formed on both opposing main surfaces of the laminated stack. The component carrier can symmetrically be manufactured.

In an embodiment of the method of manufacturing, the shielding structure is manufactured at least by one of plating, sputtering and three-dimensional printing. Assembly or mounting machines are not necessary. The shielding structure can be adapted to any shape of the structural feature and/or the cap structure. The shielding structure can be arranged at any location of the component carrier and is not limited in terms of layout or geometrical complexity of the component carrier. The shielding structure can have a variable thickness which is adapted to the desired shielding efficiency. The thickness and weight of the component carrier can be reduced as compared to a conventional component carrier having a shielding made of a prefabricated metal sheet.

In an embodiment of the method of shielding a structural feature in a component carrier, the method comprises a step of using the component carrier described above, which comprises the structural feature. In an embodiment of the method of shielding, the component carrier performs a high frequency application, in particular 5G.

In an embodiment of the method of shielding, the structural feature is shielded at least against one of electromagnetic radiation, in particular high-frequency radiation, heat radiation, infrared radiation, light, and humidity; and/or the shielding structure is configured to protect a signal integrity of a signal being transported within the structural feature.

In the context of the present application, the term “exterior surface of the laminated stack” may particularly denote an outermost surface of the laminated stack and/or a main surface of the laminated stack. The main surface of the laminated stack can be defined by an outermost laminated layer of the laminated stack. One main surface of the laminated stack can be that surface where contact pads or terminals are arranged. The main surface of the component carrier can also be that surface which is perpendicularly orientated to a direction in which layers of the component carrier are superposed onto each other. However, the scope is not limited to these definitions.

In the context of the present application, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact. The term “layer structure” may particularly denote a continuous layer, a patterned layer or a plurality of non-consecutive islands within a common plane.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming through-holes through the laminate, for instance by laser drilling or mechanical drilling, and by filling them with electrically conductive material (in particular copper), thereby forming vias as through-hole connections. Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier having substantially the same size as a component (in particular an electronic component) to be mounted thereon. More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) or a photo-imageable or dry-etchable organic material like epoxy-based build-up material (such as epoxy-based build-up film) or polymer compounds like polyimide, polybenzoxazole, or benzocyclobutene.

In an embodiment, the at least one electrically insulating layer structure comprises at least one of the group consisting of resin (such as reinforced or non-reinforced resins, for instance epoxy resin or bismaleimide-triazine resin), cyanate ester, polyphenylene derivate, glass (in particular glass fibers, multi-layer glass, glass-like materials), prepreg material (such as FR-4 or FR-5), polyimide, polyamide, liquid crystal polymer (LCP), epoxy-based build-up film, polytetrafluoroethylene (Teflon®), a ceramic, and a metal oxide. Teflon is a registered trademark of the Chemours Company FC of Wilmington, Del., U.S.A. Reinforcing materials such as webs, fibers or spheres, for example made of glass (multilayer glass) may be used as well. Although prepreg particularly FR4 are usually preferred for rigid PCBs, other materials in particular epoxy-based build-up film or photo-imageable dielectric material for substrates may be used as well. For high frequency applications, high-frequency materials such as polytetrafluoroethylene, liquid crystal polymer and/or cyanate ester resins, low temperature cofired ceramics (LTCC) or other low, very low or ultra-low DK materials may be implemented in the component carrier as electrically insulating layer structure.

In an embodiment, the at least one electrically conductive layer structure comprises at least one of the group consisting of copper, aluminum, nickel, silver, gold, palladium, and tungsten. Although copper is usually preferred, other materials or coated versions thereof are possible as well, in particular coated with supra-conductive material such as graphene.

The at least one component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. For example, the component can be an active electronic component, a passive electronic component, an electronic chip, a storage device (for instance a DRAM or another data memory), a filter, an integrated circuit, a signal processing component, a power management component, an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferromagnetic element, for instance a ferrite core) or may be a paramagnetic element. However, the component may also be a substrate, an interposer or a further component carrier, for example in a board-in-board configuration. The component may be surface mounted on the component carrier and/or may be embedded in an interior thereof. Moreover, also other components, in particular those which generate and emit electromagnetic radiation and/or are sensitive with regard to electromagnetic radiation propagating from an environment, may be used as component.

In an embodiment, the component carrier is a laminate-type component carrier. In such an embodiment, the component carrier is a compound of multiple layer structures which are stacked and connected together by applying a pressing force and/or heat.

The aspects defined above and further aspects of the invention are apparent from the examples of embodiment to be described hereinafter and are explained with reference to these examples of embodiment.

### BRIEF DESCRIPTION OF THE DRAWINGS

FIG. 1 illustrates a cross-sectional view of a component carrier according to an exemplary embodiment of the invention.

FIG. 2 illustrates a method of manufacturing a component carrier according to an exemplary embodiment of the invention.

### DETAILED DESCRIPTION OF ILLUSTRATED EMBODIMENTS

The illustrations in the drawings are schematically presented. In different drawings, similar or identical elements are provided with the same reference signs.

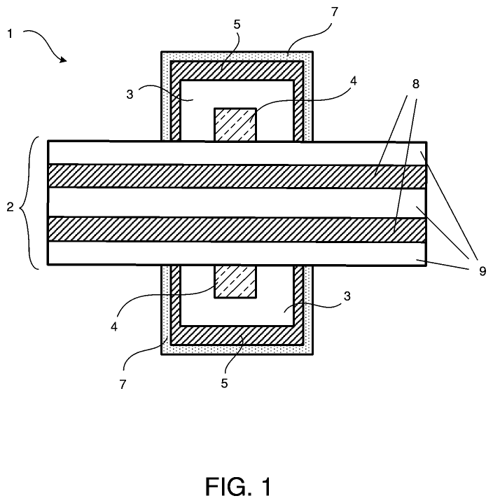

FIG. 1 illustrates a cross-sectional view of a component carrier 1 according to an exemplary embodiment of the invention. The component carrier 1 is shaped as a plate. The component carrier 1 can be configured as one of the group consisting of a printed circuit board, a substrate, and an interposer. The component carrier 1 can be configured as a laminate-type component carrier.

The component carrier 1 comprises a laminated stack 2 having a plurality of electrically conductive layer structures and a plurality of electrically insulating layer structures.

At least one of the electrically conductive layer structures of the component carrier can comprise at least one material of the group consisting of copper, aluminum, nickel, silver, gold, palladium, and tungsten, any of the mentioned materials being optionally coated with supra-conductive material such as graphene.

At least one of the electrically insulating layer structures can comprise at least one of the group consisting of resin, in particular reinforced or non-reinforced resin, for instance epoxy resin or bismaleimide-triazine resin, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide.

The component carrier 1 comprises an electrically insulating cap structure 3 selectively covering a structural feature 4 at an exterior surface of the laminated stack 2.

In the present embodiment, the electrically insulating cap structure 3 is a solder resist. In another embodiment, the electrically insulating cap structure 3 can comprise at least one of the group consisting of resin, in particular reinforced or non-reinforced resin, for instance epoxy resin or bismaleimide-triazine resin, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide, a resin, and a mold compound.

The component carrier 1 comprises a shielding structure 5 on the cap structure 3 for shielding the structural feature 4. The shielding structure 5 is arranged above the cap structure 3. The shielding structure 5 can comprise at least one of the group consisting of copper, aluminum, nickel, silver, gold, palladium, and tungsten, any of the mentioned materials being optionally coated with supra-conductive material such as graphene. The shielding structure 5 can also exclusively comprise graphene.

The shielding structure 5 shields at least against one of electromagnetic radiation, in particular high-frequency radiation, heat radiation, infrared radiation, light, and humidity. The shielding structure 5 is configured to protect a signal integrity of a signal being transported within the structural feature 4.

In an embodiment, the shielding structure 5 does not carry a signal which is used for a signal processing or a current which is used for a power supply. The shielding structure 5 is not necessarily connected to a port or pad for signal processing or power supply. In an embodiment, the shielding structure 5 does exclusively have a shielding functionality.

In the present embodiment, the structural feature 4, the cap structure 3 and the shielding structure 5 are formed only on one of both opposing main surfaces of the laminated stack 2. However, in an alternative embodiment, the structural feature 4, the cap structure 3 and the shielding structure 5 can be formed on both opposing main surfaces of the laminated stack 2. The shielding structure 5 on both opposing main surfaces of the laminated stack 2 can shield one and the same structural feature 4.

In the present embodiment, the cap structure 3 and the shielding structure 5 are substantially U-shaped in the cross-sectional view of FIG. 1.

In an embodiment, the structural feature 4 can completely be surrounded by the stack 2 and the cap structure 3 in the cross section of FIG. 1. The structural feature 4 can also completely be surrounded by the stack 2, the cap structure 3 and the shielding structure 5 in the cross section of FIG. 1. The shielding structure 5 can selectively or globally be applied on the cap structure 3, and optionally on the exterior surface of the laminated stack 2.

In the present embodiment, the structural feature 4 is an electrically conductive trace.

In another embodiment, the structural feature 4 can be an electrically conductive pad of the electrically conductive layer structures, an optical wave guide such as a glass fiber structure, and/or a connection structure connected to an antenna structure, or a component.

Such a component can be surface mounted on and/or embedded in the component carrier 1, wherein the component is in particular selected from a group consisting of an electronic component, an electrically non-conductive and/or electrically conductive inlay, a heat transfer unit, a light guiding element, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier 1, and a logic chip. The component can be surface-mounted on the exterior surface of the laminated stack 2, or the component can be embedded in a cavity in the laminated stack 2, where the cavity forms a part of the exterior surface of the laminated stack 2.

In a modified embodiment, at least one of a surface finish and a further solder resist can be formed on top of the shielding structure 5 and/or the stack 2. For example, after processing interior layer structures of the component carrier 1, the stack 2 and/or the shielding structure 5, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of the stack 2 of electrically insulating layer structures and electrically conductive layer structures, it is possible to proceed with a surface treatment of the obtained layers structures or component carrier 1.

In particular, as the further solder resist, an electrically insulating solder resist may be applied to one or both opposing main surfaces of the layer stack 2 or component carrier 1 in terms of surface treatment. For instance, it is possible to form such as the further solder resist on an entire main surface and to subsequently pattern the layer of the further solder resist so as to expose one or more electrically conductive surface portions which shall be used for electrically coupling the component carrier 1 to an electronic periphery. The surface portions of the component carrier 1 remaining covered with the further solder resist may be efficiently protected against oxidation or corrosion, in particular surface portions containing copper.

It is also possible to apply a surface finish selectively to exposed electrically conductive surface portions of the stack 2 or the component carrier 1 in terms of surface treatment. Such a surface finish may be an electrically conductive cover material on exposed electrically conductive layer structures (such as pads, conductive tracks, etc., in particular comprising or consisting of copper) on a surface of the component carrier 1 or the stack 2. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier 1. The surface finish has the function to protect the exposed electrically conductive layer structures (in particular copper circuitry) and enable a joining process with one or more components, for instance by soldering. Examples for appropriate materials for a surface finish are OSP (Organic Solderability Preservative), Electroless Nickel Immersion Gold (ENIG), gold (in particular Hard Gold), chemical tin, nickel-gold, nickel-palladium, etc.

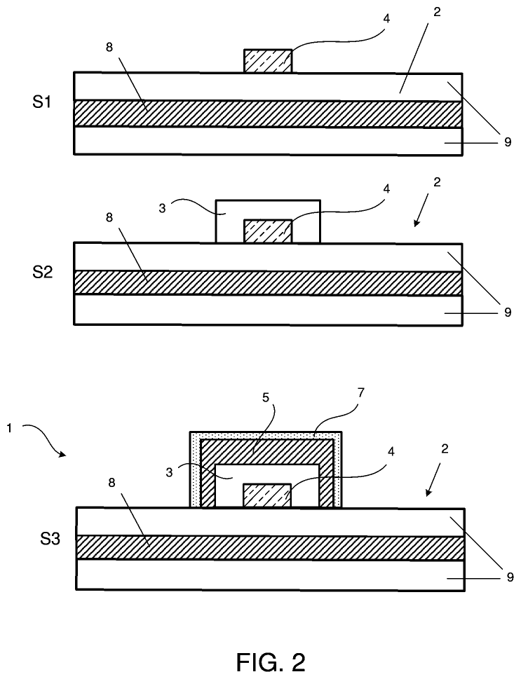

FIG. 2 illustrates a method of manufacturing a component carrier 1 according to an exemplary embodiment of the invention.

In a step S1, a laminated stack 2 having a plurality of electrically conductive layer structures and a plurality of electrically insulating layer structures (not shown) is provided. In detail, the plurality of electrically conductive layer structures comprises a structural feature 4 which is formed at an exterior surface of the laminated stack 2. In the present embodiment, the structural feature 4 is an electrically conductive trace. In another embodiment, the structural feature 4 can be an electrically conductive pad of the electrically conductive layer structures, an optical wave guide such as a glass fiber structure, and/or a connection structure connected to an antenna structure, or a component.

Such a component can be surface mounted on and/or embedded in the component carrier 1, wherein the component is in particular selected from a group consisting of an electronic component, an electrically non-conductive and/or electrically conductive inlay, a heat transfer unit, a light guiding element, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier 1, and a logic chip. The component can be surface-mounted on the exterior surface of the laminated stack 2, or the component can be embedded in a cavity in the laminated stack 2, where the cavity forms a part of the exterior surface of the laminated stack 2.

At least one of the electrically conductive layer structures of the stack 2 can comprise at least one of the group consisting of copper, aluminum, nickel, silver, gold, palladium, and tungsten, any of the mentioned materials being optionally coated with supra-conductive material such as graphene.

At least one of the electrically insulating layer structures of the stack 2 can comprise at least one of the group consisting of resin, in particular reinforced or non-reinforced resin, for instance epoxy resin or bismaleimide-triazine resin, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide.

In a step S2, an electrically insulating cap structure 3 is formed to selectively cover the structural feature 4. In the present embodiment, the electrically insulating cap structure 3 is a solder resist.

In another embodiment, the electrically insulating cap structure 3 can comprise at least one of the group consisting of resin, in particular reinforced or non-reinforced resin, for instance epoxy resin or bismaleimide-triazine resin, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide, a resin, and a mold compound.

A material of the electrically insulating cap structure 3, for example the solder resist, is applied as a paste, a dry film, a lamination film or a liquid onto the structural feature 4. The material of the electrically insulating cap structure 3 can be photoimageable and globally applied onto the structural feature 4 and optionally on the stack 2. Thereafter, the material of the electrically insulating cap structure 3 is selectively cured and exposed, for example by means of heat or UV light, and the remaining unexposed material of the electrically insulating cap structure 3 can be removed, for example by stripping.

Alternatively, the material of the electrically insulating cap structure 3 can be applied by screen printing, spraying or curtain coating, or it can selectively be applied by ink jet printing.

In a step S3, a shielding structure 5 is formed on the cap structure 3 for shielding the structural feature 4. The shielding structure 5 can be manufactured at least by one of plating, sputtering and three-dimensional printing. In case of plating, a thin seed layer can chemically be applied on the cap structure 3, which is followed by a galvanic plating step on the thus formed seed layer.

The shielding structure 5 can also be formed by subtractive or additive processes. As additive processes, SAP (Semi-additive processes) or mSAP (modified Semi-additive processes) can be utilized.

The shielding structure 5 can selectively or globally be applied on the cap structure 3, and optionally on the exterior surface of the laminated stack 2.

In an embodiment, the shielding structure 5 does not carry a signal which is used for a signal processing or a current which is used for a power supply. The shielding structure 5 is not necessarily connected to a port or pad for signal processing or power supply. In an embodiment, the shielding structure 5 does exclusively have a shielding functionality.

In the present embodiment, the structural feature 4, the cap structure 3 and the shielding structure 5 are formed on only one of the opposing main surfaces of the laminated stack 2. In an alternative embodiment, the cap structure 3 and the shielding structure 5 can be formed on both opposing main surfaces of the laminated stack 2. The shielding structure 5 on both opposing main surfaces of the laminated stack 2 can shield one and the same structural feature 4. The component carrier 1 can symmetrically be formed, that is, the structural features 4, the cap structures 3 and the shielding structures 5 are arranged on both opposing main surfaces of the laminated stack 2.

In an embodiment, the component carrier 1 can perform a high frequency application, in particular 5G. The structural feature 4 can be shielded at least against one of electromagnetic radiation, in particular high-frequency radiation, heat radiation, infrared radiation, light, and humidity. In general, the shielding structure 5 is configured to protect a signal integrity of a signal being transported within the structural feature 4.

In the present embodiment, the cap structure 3 and the shielding structure 5 are formed to be substantially U-shaped in the cross-sectional view of FIG. 2 so that the structural feature 4 is shielded even at the lateral sides.

In an embodiment, the structural feature 4 can completely be surrounded by the stack 2 and the shielding structure 5 in the cross section of FIG. 2. The structural feature 4 can also completely be surrounded by the stack 2, the cap structure 3 and the shielding structure 5 in the cross section of FIG. 2.

In a modified embodiment, at least one of a surface finish and a further solder resist can be formed on top of the shielding structure 5 and/or the stack 2. For example, after processing interior layer structures of the component carrier 1, the stack 2 and/or the shielding structure 5, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of the stack 2 of electrically insulating layer structures and electrically conductive layer structures, it is possible to proceed with a surface treatment of the obtained layers structures or component carrier 1.

In particular, as the further solder resist, an electrically insulating solder resist may be applied to one or both opposing main surfaces of the layer stack 2 or component carrier 1 in terms of surface treatment. For instance, it is possible to form such as the further solder resist on an entire main surface and to subsequently pattern the layer of the further solder resist so as to expose one or more electrically conductive surface portions which shall be used for electrically coupling the component carrier 1 to an electronic periphery. The surface portions of the component carrier 1 remaining covered with the further solder resist may be efficiently protected against oxidation or corrosion, in particular surface portions containing copper.

It is also possible to apply a surface finish selectively to exposed electrically conductive surface portions of the stack 2 or the component carrier 1 in terms of surface treatment. Such a surface finish may be an electrically conductive cover material on exposed electrically conductive layer structures (such as pads, conductive tracks, etc., in particular comprising or consisting of copper) on a surface of the component carrier 1 or the stack 2. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier 1. The surface finish has the function to protect the exposed electrically conductive layer structures (in particular copper circuitry) and enable a joining process with one or more components, for instance by soldering. Examples for appropriate materials for a surface finish are OSP (Organic Solderability Preservative), Electroless Nickel Immersion Gold (ENIG), gold (in particular Hard Gold), chemical tin, nickel-gold, nickel-palladium, etc.

It should be noted that the term “comprising” does not exclude other elements or steps and the article “a” or “an” does not exclude a plurality. Also, elements described in association with different embodiments may be combined.

Implementation of the invention is not limited to the preferred embodiments shown in the figures and described above. Instead, a multiplicity of variants is possible which use the solutions shown and the principle according to the invention even in the case of fundamentally different embodiments.

1. A component carrier, comprising:
a laminated stack comprising a plurality of electrically conductive layer structures and a plurality of electrically insulating layer structures;
an electrically insulating cap structure selectively covering a structural feature at an exterior surface of the laminated stack, the structural feature is at least one of an optical waveguide and a connection structure connected to an antenna structure; and
a shielding structure on the cap structure for shielding the structural feature.

2. The component carrier according to claim 1, wherein the electrically insulating cap structure is a solder resist.

3. The component carrier according to claim 1, wherein the structural feature, the cap structure and the shielding structure are formed on both opposing main surfaces of the laminated stack.

4. The component carrier according to claim 1, wherein in a cross-sectional view, the cap structure is substantially U-shaped.

5. The component carrier according to claim 1, wherein in a cross-sectional view, the shielding structure is substantially U-shaped.

6. (canceled)

7. The component carrier according to claim 1, wherein the structural feature is a component.

8. The component carrier according to claim 1, wherein the shielding structure shields at least against one of electromagnetic radiation, in particular high-frequency radiation, heat radiation, infrared radiation, light, and humidity; and/or
the shielding structure is configured to protect a signal integrity of a signal being transported within the structural feature.

9. The component carrier according to claim 1, wherein on top of the shielding structure, at least one of a surface finish and a further solder resist is formed.

10. The component carrier according to claim 1, further comprising at least one of the following features:
the component carrier comprises at least one component being surface mounted on and/or embedded in the component carrier, wherein the at least one component is in particular selected from a group consisting of an electronic component, an electrically non-conductive and/or electrically conductive inlay, a heat transfer unit, a light guiding element, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier, and a logic chip;
wherein at least one of the electrically conductive layer structures of the component carrier comprises at least one of the group consisting of copper, aluminum, nickel, silver, gold, palladium, and tungsten, any of the mentioned materials being optionally coated with supra-conductive material such as graphene;
wherein the shielding structure comprises at least one of the group consisting of copper, aluminum, nickel, silver, gold, palladium, and tungsten, any of the mentioned materials being optionally coated with supra-conductive material such as graphene; wherein the electrically insulating layer structure comprises at least one of the group consisting of resin, in particular reinforced or non-reinforced resin, for instance epoxy resin or bismaleimide-triazine resin, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide;
wherein the electrically insulating cap structure comprises at least one of the group consisting of resin, in particular reinforced or non-reinforced resin, for instance epoxy resin or bismaleimide-triazine resin, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide, a resin, and a mold compound;
wherein the component carrier is shaped as a plate;
wherein the component carrier is configured as one of the group consisting of a printed circuit board, a substrate, and an interposer;
wherein the component carrier is configured as a laminate-type component carrier.

11. A method of manufacturing a component carrier, the method comprising:
providing a laminated stack having a plurality of electrically conductive layer structures and a plurality of electrically insulating layer structures;
forming an electrically insulating cap structure selectively covering a structural feature at an exterior surface of the laminated stack, the structural feature is at least one of an optical waveguide and a connection structure connected to an antenna structure; and
forming a shielding structure on the cap structure for shielding the structural feature.

12. The method according to claim 11, wherein the electrically insulating cap structure is a solder resist.

13. The method according to claim 11, wherein the structural feature, the cap structure and the shielding structure are formed on both opposing main surfaces of the laminated stack.

14. The method according to claim 11, wherein the shielding structure is manufactured at least by one of plating, sputtering and three-dimensional printing.

15. A method of shielding a structural feature in a component carrier, wherein the method comprises a step of using a component carrier with the structural feature, the component carrier configured with a laminated stack comprising a plurality of electrically conductive layer structures and a plurality of electrically insulating layer structures;
an electrically insulating cap structure selectively covering a structural feature at an exterior surface of the laminated stack, wherein the structural feature is at least one of an optical waveguide and a connection structure connected to an antenna structure; and
a shielding structure on the cap structure for shielding the structural feature.

16. The method according to claim 15, wherein the component carrier performs a high frequency application, in particular 5G.

17. The method according to claim 15, wherein the structural feature is shielded at least against one of electromagnetic radiation, in particular high-frequency radiation, heat radiation, infrared radiation, light, and humidity; and/or
the shielding structure is configured to protect a signal integrity of a signal being transported within the structural feature.
